(19) United States
(12) Patent Application Publication
(10) Pub. No.: US 2010/0097326 A1
(43) Pub. Date: Apr. 22, 2010

(54) KEYBOARD-VIDEO-MOUSE SWITCH SYSTEM WITH INTERACTIVE DISPLAY

(76) Inventor: YU-TING LIANG, Longtan Township (TW)

Correspondence Address: Patterson & Sherldan - ATEN, 3040 Post Oak Boulevard, Suite 1500, Houston, TX, 77056, US

(21) Appl. No.: 12/255,208

(22) Filed: Oct. 21, 2008

(51) Int. Cl. G06F 3/041; H05K 7/00

(52) U.S. Cl. 345/173; 361/679.02

(57) ABSTRACT

Embodiments of the present invention describe an interactive display system and method for using the same. In one embodiment, an interactive display system includes a KVM switch system and a display panel. The KVM switch system has an input port and a plurality of output ports. The output port is configured to be coupled to computer servers. The display panel is coupled to the input port of the KVM switch system. The display panel includes a first zone for displaying video information, a second zone comprising a keyboard, and a third zone comprising a plurality of buttons.

### BACKGROUND

1. Field of the Invention

Embodiments of the present invention generally relate to a keyboard-video-mouse (KVM) switch system with an interactive display.

2. Description of the Related Art

Many computer servers capable of performing general purpose and specialized tasks require a computer room with raised floor and air conditioning. Due to increasingly reduced office space and high expense of the computer room, space occupied by computer servers must also be reduced. Typically, a computer mountable rack is utilized in the computer room to maximize the computer room space for computer server management. Keyboard-Video-Mouse (KVM) switch system has been developed to allow a single video display, a character input device and a pointing device to communicate with one or more computers mounted in the rack.

As computer server management and space utilization become more critical in office space, the space allocated for positioning the video display, character input and pointing device has become increasingly small, and as such, difficult to accommodate while still enabling a convenient user interface. Additionally, the space required for the video display, character input and pointing device in the rack significantly reduces the space available for additional computer servers. Furthermore, the hardware, such as slides, used to couple the video display, character input and pointing device also consumes valuable rack space. Since the most systems use multiple sliders, the potential for mechanical failure is high.

Therefore, there is a need for a KVM system having an improved video display monitor, character input and a pointing device. Additionally, there is a need for an improved interactive display for a KVM system.

### SUMMARY OF THE INVENTION

Embodiments of the invention describe an interactive display system and method for using the same. In one embodiment, an interactive display system includes a KVM switch system and a display panel. The KVM switch system has an input port and a plurality of output ports. The output port is configured to be coupled to computer servers. The display panel is coupled to the input port of the KVM switch system. The display panel includes a first zone for displaying video information, a second zone comprising a keyboard, and a third zone comprising a plurality of buttons.

In another embodiment, a method for operating an interactive display system includes generating a signal from at least one zone of a touch screen, transmitting the signal from the touch screen to a KVM switch system, processing the signal in the KVM switch system, and transmitting a signal to a server in response to the processed signal.

In yet another embodiment, a server system is provided that includes a plurality of servers, a KVM switch system and an interactive display panel coupled to a rack. The interactive display panel is coupled in communication with the KVM switch system. The interactive display panel has a touch screen and keyboard viewable on a first side of the panel. The first side of the panel faces downward when in a position retracted into the rack. The panel is rotatable to expose the first side of the panel when extended from the rack.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIG. 1 depicts a schematic diagram of hardware components comprising an interactive display system in accordance with one embodiment of the present invention;

FIGS. 2A-D depict different embodiments of an interactive display system;

FIG. 3 depicts a flow diagram for using an interactive display system to control computer serves connected to a KVM switch; and

FIG. 4 is a side view of one embodiment of a server rack for use with the invention.

It is to be noted, however, that the appended drawings illustrate only typical embodiments of this invention and are therefore not to be considered limiting of its scope, for the invention may admit to other equally effective embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention include an interactive display system that includes an interactive display panel used with a KVM switch system. In one embodiment, the interactive display panel includes a video display, a keyboard and a pointing device integrated with the video display. In some embodiments, the interactive display panel includes a screen segment in different zones. Signals produced in response to touching the zones are communicated to remote computer servers through the KVM switch system.

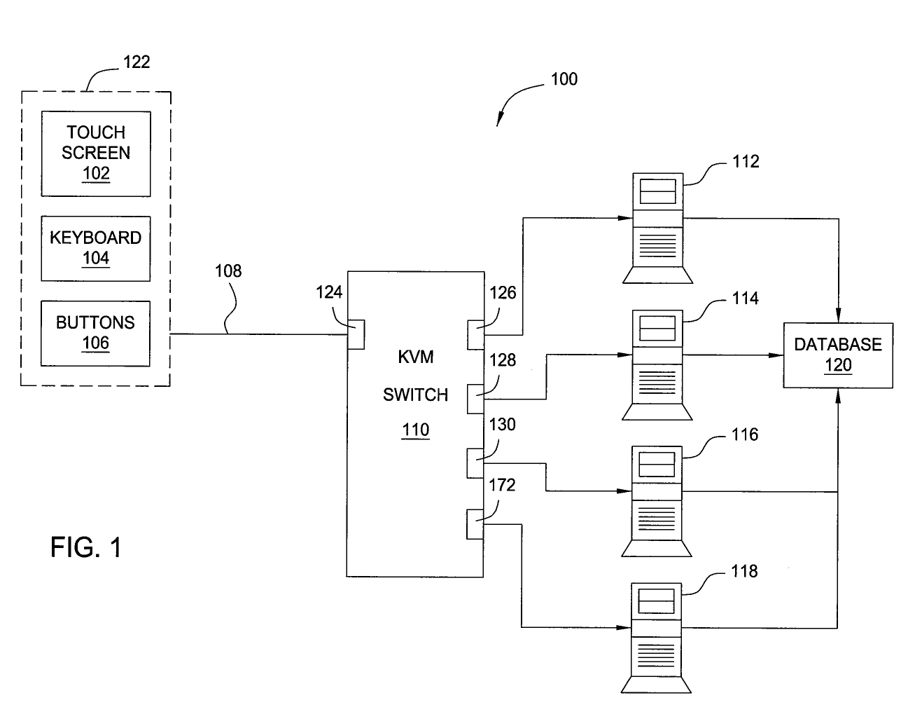

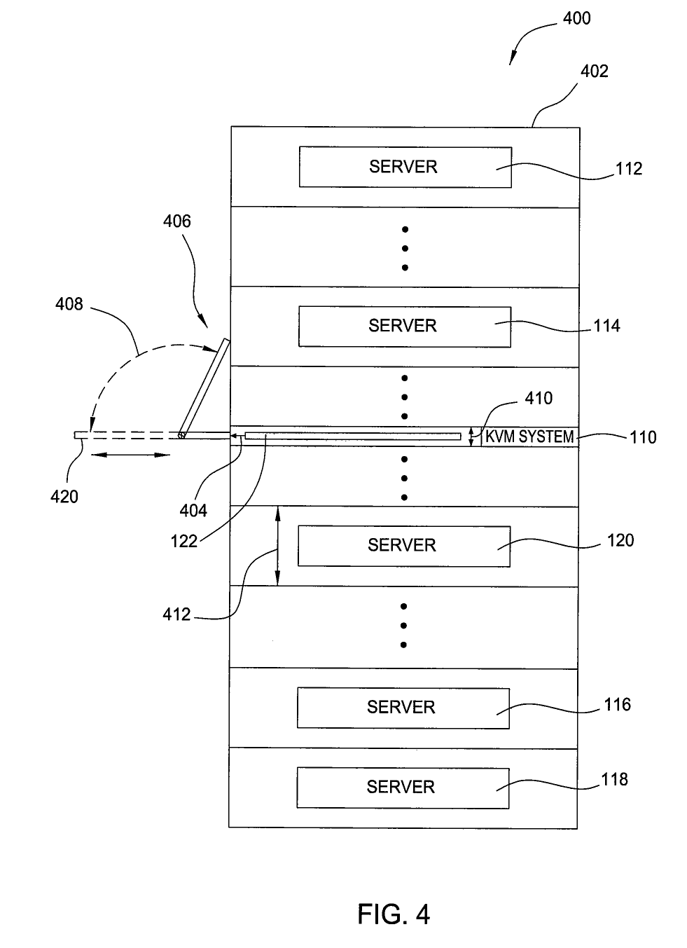

FIG. 1 depicts a schematic diagram of hardware components comprising an interactive display system 100 in accordance with one embodiment of the present invention. In one embodiment, the interactive display system 100 includes the interactive display panel 122 and a KVM switch system 110. One or more computer servers, shown as servers 112, 114, 116, 118 in FIG. 1, are connected to the KVM switch system 110. It is noted that the interactive display panel 122, the KVM switch system 110, and the computer servers 112, 114, 116, 118 may be positioned and mounted in a server rack or other space-saving structure for organization and for ease of space management. An exemplary server rack is described below with reference to FIG. 4. The interactive display panel 122 is coupled to and communicates with the KVM switch system 110 through a cable 108. The cable 108 may be a metal conductor, USB, fiber optic cable, or other suitable data communication device. It is also contemplated that the panel 122 may communicate with the KVM switch system 110 wirelessly. The plurality of computer servers 112, 114, 116, 118 are coupled to the KVM switch system 110 and communicate to the interactive display panel 122. The computer servers 112, 114, 116, 118 may be further and optionally connected to a database server 120 capable of storing additional information.

In one embodiment, the interactive display panel 122 includes a touch screen 102. The touch screen 102 may display video information transmitted from the KVM switch system 110. The display panel 122 may also an integrated keyboard 104. Alternatively, the keyboard 104 may be operably displayed on the touch screen 102. The display panel 122 may also include a plurality of function buttons 106. The function buttons 106 have a predetermined command associated therewith. Alternatively, the function buttons 106 may be operably displayed on the touch screen 102.

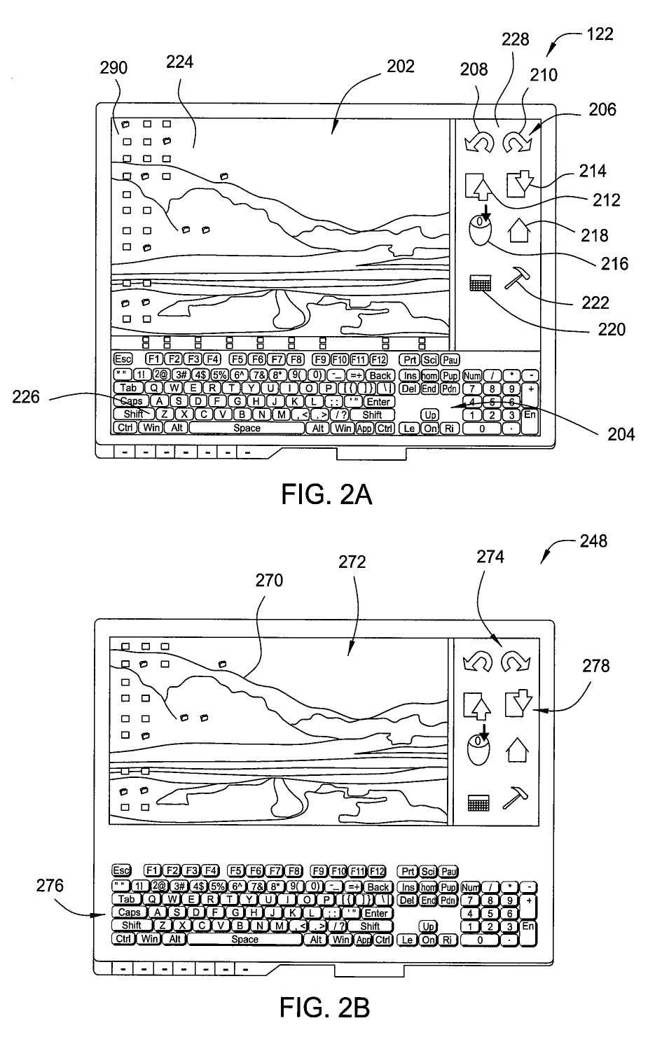

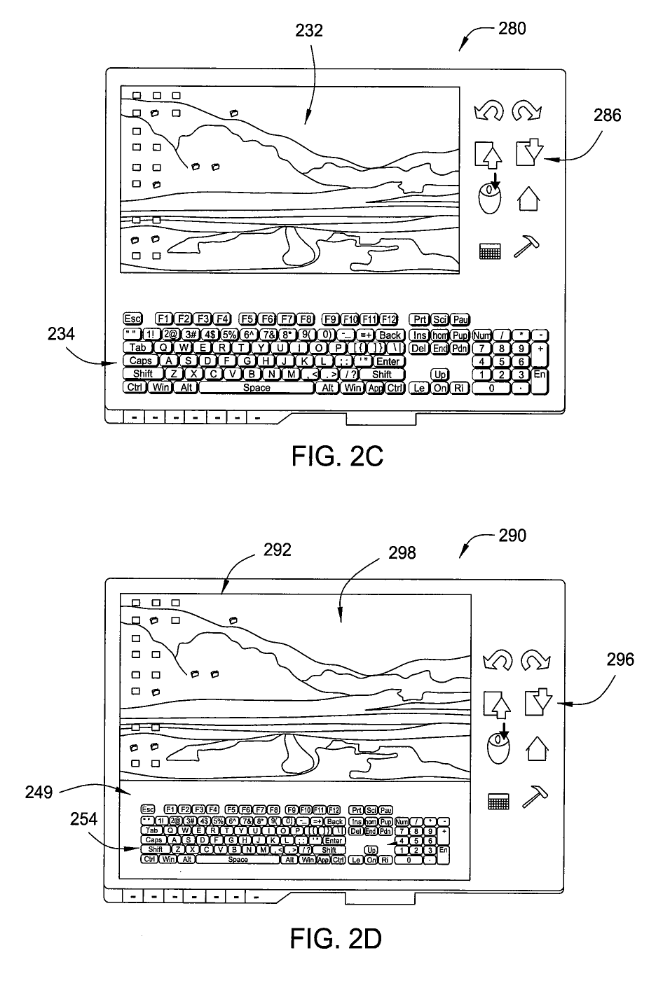

The touch screen 102 provides optical user interface that allows the user to view information and communicate through KVM switch system 110 with the servers by generating a command by the user touch or pressure input on the touch screen 102. The touch screen 102 may be a LCD monitor, or other suitable display devices that provide high resolution for multimedia display. In one embodiment, the touch screen 102 may have a diagonal of between about 17 inches and about 25 inches. In one embodiment, the touch screen 102 may be any suitable touch screens commercially available from any display manufactures. A detail description regarding the configuration of the interactive display panel 122 will be discussed in greater detail below with referenced to FIGS. 2A-2D.

In one embodiment, the KVM switch system 110 has at least one input port 124 and a plurality of output ports, shown in one embodiment as output ports 126, 128, 130, 172. The input port 124 is coupled by the cable 108 to the display panel 122 and receives signal associated with an action request command, or signals, from the display panel 122. The action request command may be generated by one or more of the keyboard 104, function buttons 106 or touch screen 102. The KVM switch system 110 includes a program embodied in the hardware or software saved in a memory of the system 110 that, when executed by a processor of the system 110, processes the incoming signals received from the display panel 122 and outputs an outgoing signal that is associated with action request command. The incoming signals from the display panel 122 are processed by a processor disposed in the KVM switch system 110 and formatted into an output signal that is transmitted through the output ports 126, 128, 130, 172 to the designated computer servers 112, 114, 116, 118. In one embodiment, the incoming signals may be utilized to select which of output ports 126, 128, 130, 172 is connected to the inlet port 124 so that information from a selected one of the computer servers 112, 114, 116, 118 may be viewed on the touch screen 102. The output signal may request information, data or a response from the computer servers 112, 114, 116, 118 to which the output signal was directed. The computer server to which the output signal was directed provides a response signal to the KVM switch system 110. The processor of the KVM switch system 110 processes the response signal and provides information in a designated location on the touch screen. As information associated with the response signal is updated and displayed on the interactive display panel 122, the user may continue to interact with the interactive display system 100. The interactive display panel 122 can interface and process multiple data requests communicating with different computer servers 112, 114, 116, 118 simultaneously through the KVM switch system 110 so that information can be conveyed bi-directions between the interactive display panel 122 and multiple locations of the computer servers 112, 114, 116, 118 at the same time.

In one embodiment, the computer servers 112, 114, 116, 118 is connected to the database server 120 via computer network, such as Ethernet, Broadband Internet connection, corporate LAN/WAN, intranet connection, fiber optic cable, wireless interface, or other suitable data communication techniques. In some embodiments, the computer servers 112, 114, 116, 118 and the database server 120 may be in form of a single machine, or alternatively, may be separate equipments so that various database servers may be coupled or be accessed by proper arrangement. In one embodiment, the computer servers 112, 114, 116, 118 and/or database server 120 includes memory in form of hard drive capacity, modems, RAM, network interface components, a central processing unit, and an optimized video hardware/software as needed.

In one embodiment, the interactive display system 100 may be installed in a server rack for improved space management. The server rack may include an uninterruptable power supply that provides reliable power to the interactive display panel, the KVM switch system and servers coupled thereto. The KVM switch system 110 allows user to switch between visual display panels 122 and select a particular computer server 112, 114, 116, 118 or database server 120 to work on. Using the single display panel 122 that can be used to display of each of the selected computer server 112, 114, 116, 118 or database server 120 significantly saves space in the server rack and reduces cost of monitors or keyboard required for each individual selected computer server or database server control. The KVM switch system 110 can allow as many as computer servers or database servers as desired to be mounted on the server rack sharing the same display panel 122. Several racks may be assembled together to boost the space capacity through one KVM switch system 110 while keeping using one display panel 122 for control.

FIG. 2A depicts one embodiment of the interactive display panel 122 having areas designated for the performing the functions of a keyboard, video and mouse (KVM) that are integrated into a single unit. In one embodiment, the interactive display panel 122 has a first side 290 on which the touch screen 102 is disposed. The touch screen 102 may be apportioned into one or more zones. Each zone is configured to have different work functions and allow users to input different commands thereon. For example, the touch screen 102 may be divided into a first zone 202, a second zone 204 and a third zone 206. At least the first zone 202 is utilized as a display with pointer function. Other zones may include keyboard and/or button functions.

In one embodiment, three zones 202, 204, 206 disposed on the first side 290 are be defined on the touch screen 102. In other embodiments, the touch screen 102 may embody two zones, for example, the display with pointer function and one of the keyboard or button function. The zones may be configured to allow the user to select which zones are displayed. For example, the user may select between displaying one, two or three selected zones at a single time.

In one embodiment, the first zone 202 of the touch screen 102 is a display area that provides a video output to display video information provided from the KVM switch system 110. The first zone 202 may be a mouse control zone controllable by a mouse installed to the touch screen 102. Alternatively, the first zone 202 may be a touch sensitive zone that generates a signal in response to a touch from a user.

In one embodiment, the first zone 202 of the touch screen 102 may display information of the computer servers 112, 114, 116, 118 and the database server 120 formatted via the KVM switch system 110. The first zone 202 of the touch screen 102 displays optimized information of multimedia from the computer servers 112, 114, 116, 118 through the KVM switch system 110. The first zone 202 of the touch screen 102 may also display industry standard operating system transmitted from the computer servers 112, 114, 116, 118 and the database server 120, such as Microsoft Windows, Linux, Unix, Lotus, Apple Mac OX and the like, with industry standard web browser, such as Netscape Navigator, Microsoft Internet Explorer, Safari, Mosaic, Mozilla Firefox, AOL Explorer, and the like.

In one embodiment, the second zone 204 is embodied on the touch screen 102 and is configured to display the buttons 106 as a tool bar 228 that provides different function icons that allow users to input different command and/or data requests. In one embodiment, the tool bar 228 is touch activated.

In another embodiment, both the first zone 202 displaying information of the computer servers 112, 114, 116, 118 and the second zone 204 operably displaying the buttons 106 are touch activated.

In an alternative embodiment, the second zone 204 is not part of the touch screen 102 and is located on a separate area on the first side 290 of the display 122. In this particular embodiment, the buttons 106 are operably isolated from the first zone 202 defined on the touch screen 102 and is mechanically operated, for example by a mechanical, optical or electrical switch, instead of touch activated.

In one embodiment, the buttons 106 are located in the third zone 206 defined on the touch screen 102 and shown as a tool bar 228. In the embodiment of FIG. 2A, the tool bar 228 includes a back button 208 and a forward button 210. The back button 208 and forward button 210 allows the user to scroll through which server is displayed on the touch screen 102 by controlling which output ports 126, 128, 130, 172 of the KVM switch system 110 is providing information to the touch screen 102. Thus, actuation of the back button 208 and forward button 210 allow efficient switching of the information transmitted from different output ports of the KVM switch system 110 to the touch screen 102

In another embodiment, the buttons 106 may includes a first go-to button 212 and a second go-to button 214. The first go-to button 212 and/or the second go-to button 214 allows information to be displayed on the touch screen from a predetermined server. For example, actuation of the first go-to button 212 causes the touch screen 102 to display information provided through a first predefined one of the outlet ports 126, 128, 130, 172 of the KVM switch system 110 without scrolling through information from the non-selected servers. Actuation of the second go-to button 214 causes the touch screen 102 to display information provided through a second predefined one of the outlet ports 126, 128, 130, 172 of the KVM switch system 110 without scrolling through information from the non-selected servers.

Furthermore, the buttons 106 may include a mouse right click set button 216. When the mouse right click set button 216 is actuated, a task icon selected using a pointer viewable in the touch screen 102 is translated into an execution ready status. A touch of the execution ready icon on the touch screen 102 will execute the software program associated with the highlighted icon. The execution ready status may be inactivated by a second actuation of the mouse right click set button 216.

Additional function icons 218, 220, 222 may be employed to provide different control functions and execution of selected programs of the remote computer servers 112, 114, 116, 118, database servers 120 and the KVM switch system 110. For example, the functional icon 218 may provide an “auto scan” function. When activated, the KVM switch 110 can determine which ports coupled to which computer servers 112, 114, 116, 118 or database servers 120. Furthermore, another functional icon 220 may be configured as a “hot key setting” or “fast key setting” that directs to a particular software program or computer server commonly or frequently utilized by users. Some other functional icons 222 may be reserved in the tool bar 228 so allow custom configuration by a user.

In one embodiment, the second zone 204 of the touch screen 102 may be configured operably display a keyboard input system 226 as the keyboard 104. The keyboard input system 226 allows user to key in text, commands and the like. The text and commands may be used for maintenance and updates to the data information stored in the computer servers 112, 114, 116, 118 and database servers 120.

In one embodiment, the keyboard input system 226 may be displayed and/or included as a portion of the touch screen 102 that may be touch activated. In this particular embodiment, both keyboard input system 226 and the monitor display 224 are touch activated.

In an alternative embodiment, the keyboard 104 may be disposed on the first side 290 of the panel 122 outside of the touch screen 102. In this particular embodiment, the keyboard 104 is operably isolated from the touch screen 102 and is mechanically controlled instead of touch activated.

In the embodiment wherein the entire display panel 122 is configured as a touch screen 102, one of the buttons may be configured to hide the keyboard input system 226. When the “hide” button is activated, the keyboard input system 226 may be toggled between an operably visible and hidden state. When the keyboard input system 226 is in a hidden state, the first zone 202 of the touch screen utilized for display information may be enlarged for enhanced viewing.

FIG. 2B depicts another embodiment of the interactive display panel 248 also having functions of keyboard, video and mouse (KVM) integrated in a single panel 248. As described above, the interactive display panel 248 includes a touch screen 270 that may be divided into different zones designated for different function areas. In one embodiment, the touch screen 270 includes a first zone 272 and a second zone 274 respectively configured to have at least one of a keyboard function, video display function, tool bar (button) function, mouse function, or other functions. The function may be located in a selected zone as needed. Additionally, the interactive display panel 248 may be divided into as many zones as many as desired.

In the exemplary embodiment depicted in FIG. 2B, the first zone 272 of the touch screen 270 provides a video display function and a pointer function, while the second zone 274 provides a button function. A keyboard 276 is located adjacent the display panel 248. Although the keyboard 276 is shown located below the touch screen 270, the keyboard 276 may be located above or to the side of the touch screen 270. In the embodiment depicted in FIG. 2B, the keyboard 276 is separate from the touch screen 270.

The second zone 274 of the touch screen 270 includes buttons 278 are operably displayed on the touch screen 270. The buttons 278 may be configured to provide the functions as described above.

FIG. 2C depicts another embodiment of the interactive display panel 280 also having functions of keyboard, video and mouse (KVM) integrated in a single panel 280. As described above, the interactive display panel 280 may be divided into different areas designed for different functions. In one embodiment, each area may respectively be configured to have at least one of a keyboard function, video display function, tool bar (button) function, mouse function, or other functions. In the exemplary embodiment depicted in FIG. 2C, the panel 280 includes a first area having a touch screen 232 having video and pointer functions, a second area having a keyboard 234 and a third area having buttons 286. In this particular embodiment, the keyboard 234 and buttons 286 are not part of the touch screen 232.

FIG. 2D depicts another embodiment of the interactive display panel 290 also having functions of keyboard, video and mouse (KVM) integrated in the single panel 290. As described above, the interactive display panel 290 may be divided into different areas designed for different functions. In one embodiment, each area may respectively be configured to have at least one of a keyboard function, video display function, tool bar (button) function, mouse function, or other functions. In the exemplary embodiment depicted in FIG. 2D, the panel 290 includes a first area having a touch screen 292 and a second area having buttons 296. The touch screen 292 is divided into at least two zones 298, 249. The first zone 298 of the touch screen 292 provides video and pointer functions. The second zone 249 of the touch screen 292 provides the keyboard function by having a keyboard 254 operably displayed thereon. In this particular embodiment, the buttons 296 are not part of the touch screen 292.

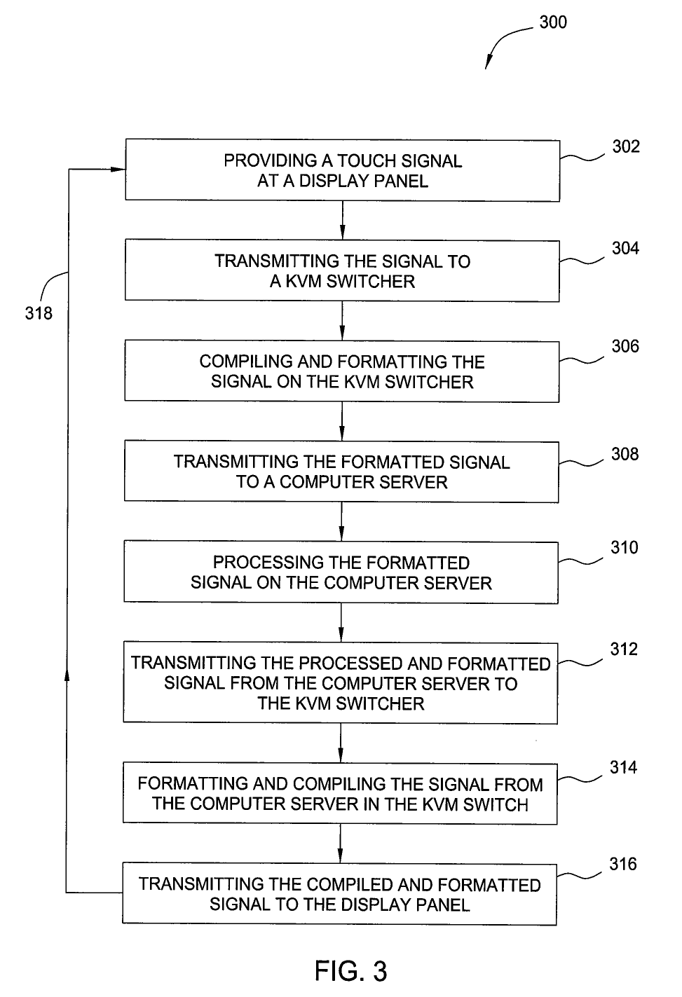

FIG. 3 depicts a flow diagram for a method 300 of operating the interactive display panel 122 to control remote computer servers 112, 114, 116, 118 and/or database servers 120 connected to the KVM switch system 110. The method 300 starts at step 302 by generating a signal from the interactive display panel 122 in response to interaction from a user. The signal may be received by the interactive display panel 122 in response to actuation of one of the push buttons, keyboard stroke, or touch to the touch screen. At step 304, the signal is transmitted to the KVM switch system 110 from the panel 122. At step 306, the signal transmitted to the KVM switch system 110 is processed by the processor of the KVM switch system 110 to generate a corresponding output signal associated with the input signal. As users may input data request in different zones of the touch screen, upon received, the program of the KVM switch system 110 analyzes and identifies which zones that the data request may be input from so that an appropriate output may be made. In one embodiment, the program of the KVM switch system 110 maps X and Y coordinate from the input data request and correlates the mapped X and Y coordinate with a link to a corresponding function area/zone in the remote computer servers 112, 114, 116, 118 and database server 120 to determine a proper command or data request to be transmitted thereto for proper execution of the data request.

For example, in the embodiment wherein the signal is input from the touch screen e.g., a mouse control zone, the signal transmitted to the KVM switch system 110 is processed and analyzed to determine a corresponding function request (e.g, output signal). The corresponding function request is generated and transmitted through the KVM switch system 110 to the appropriate remote computer servers 112, 114, 116, 118 for execution. In another embodiment wherein the signal corresponds to an input on the keyboard module system 226 of the touch screen, the processor of the KVM switch system 110 detects from the X and Y coordinates of the signal and provide an output signal indicative of a character and/or text command to the appropriate remote computer servers 112, 114, 116, 118. Similar to other input signals generated in response to user interaction with other functional zones of the touch screen, the processor of the KVM switch system 110 will be able to identify the information on which zone the information was made on the display panel 122 and compile the received data request in the KVM switch system 110, and transmitted the compiled data request to a proper function area of the remote servers for execution.

At step 308, as discussed above, as the data request has been compiled and formatted in the KVM switch system 110, the compiled data request is then transmitted to computer and/or database servers. At step 310, the compiled data transmitted to the computer and database server for data process and command execution. At step 312, as data request has been processed, the data request or information is therefore executed and/or updated in the computer and/or database server. The computer and/or database server then submits a feedback signal through KVM switch system 110 to the interactive display panel 122. At step 314, the feedback signal from the computer servers 112, 114, 116, 118 and/or database server 120 is compiled and formatted so that the signal can be communicated with the interactive display panel and reflected at a proper zone of the touch screen or function area of the interactive display panel 122. At step 316, after the feedback signal has been compiled and formatted in an interactive display panel readable format, a proper signal reflection is then displayed on the interactive display panel 122. It is noted that the method 300 of operating the interactive display panel 122 to retrieve data through KVM switch system 110 may be performed repeatedly, as shown by loop 318, as many times as needed.

FIG. 4 depicts a side view of one embodiment of a server rack 402 having the interactive display system 100 may be mounted thereon. The server rack 402 is divided into several individual server receiving slots that allow the plurality of servers 112, 114, 116, 118, 120 to be mounted therein. Each server receiving slot has a height 412 sufficient to allow a respective one of the servers to be positioned therein. The KVM switch system 110 having the interactive display panel 122 coupled thereto is mounted in one of the slots of the server rack 402. As the interactive display panel 122 has the touch screen, mouse, and keyboard integrated therein, the space required for the display panel storage is reduced as compared to the space required for conventional stacked display and keyboard KVM system. Since a height 410 required for the panel 122 is about half of the height 412 required for conventional KVM systems, more space is available on the rack 402 which may be utilized for additional servers. When extending into an operational state, the interactive display panel 122 is moved in a horizontal direction 404 outward from the rack 402 and rotated to a substantially vertical position 406, to expose the touch screen, as shown by phantom line 408. As a horizontal plane 420 needed to house a keyboard utilized for conventional KVM systems is eliminated, the space formerly occupied by the keyboard and mouse mechanisms may be therefore utilized for other equipments, such as additional servers.

Thus, an interactive display system has been developed to provide an interactive display panel to control several computer servers or database servers through a KVM switch system. The interactive display panel having a keyboard zone, tool bar zone, and a display zone integratedly formed in the panel is provided in the interactive display system to efficiently control remote servers through the KVM switch system The integrated interactive display panel efficiently eliminates use of a separate keyboard and a mouse equipment so that rack space may be allocated for other equipment.

While the foregoing is directed to embodiments of the present invention, other and further embodiments of the invention may be devised without departing from the basic scope thereof, and the scope thereof is determined by the claims that follow.

What is claimed is:

1. An interactive display system, comprising:
a KVM switch system having an input port and a plurality of output ports, the output port configured to be coupled to computer servers; and
a display panel coupled to the input port of the KVM switch system, the display panel comprising:
a first zone for displaying video information;
a second zone comprising a keyboard; and
a third zone comprising a plurality of buttons.

2. The system of claim 1, wherein the plurality of buttons operable to generate a signal to the KVM switch system.

3. The system of claim 1, wherein the first zone of the display panel is a touch screen.

4. The system of claim 3, wherein the second zone is also defined in the touch screen, wherein the plurality of buttons is operably displayed on the touch screen.

5. The system of claim 4, wherein the third zone is defined in the touch screen, wherein the keyboard is operably displayed on the touch screen.

6. The system of claim 3, wherein the third zone is defined in the touch screen, wherein the keyboard is operably displayed on the touch screen.

7. The system of claim 3, wherein the keyboard is adjacent to the touch screen.

8. The system of claim 1, wherein the plurality of buttons operable to generate a signal to the KVM switch system, wherein at least one of the buttons controls the selection of which server information is displayed on the first zone of the display panel.

9. A method for operating an interactive display system, comprising:
receiving a signal from at least one zone of a touch screen;
transmitting the signal from the touch screen to a KVM switch system;
processing the signal in the KVM switch system; and
transmitting a signal to a server in response to the processed signal.

10. The method of claim 9, receiving a signal further comprises:
receiving a signal associated with a keyboard displayed on the touch screen.

11. The method of claim 9, receiving a signal further comprises:
receiving a signal associated with a button displayed on the touch screen.

12. The method of claim 9 further comprising:
receiving a signal associated with a button displayed on the touch screen:
transmitting the signal associated with the button from the touch screen to a KVM switch system;
processing the signal associated with the button in the KVM switch system; and
transmitting a signal to a server in response to the processed signal associated with the button.

13. The method of claim 9, wherein processing the signal in the KVM switch system further comprises:
formatting the signal into a form readable by the server.

14. The method of claim 9, wherein processing the signal in the KVM switch system further comprises:
correlating coordinates associated the signal received from the touch screen with a corresponding function.

15. The method of claim 11 further comprising:
pulling the touch screen out of a server rack having a keyboard facing downward; and
rotating the touch screen from a horizontal position to expose the keyboard.

16. A server system, comprising:
a rack;
a plurality of servers mounted to the rack;
a KVM switch system coupled to the rack; and
an interactive display panel slidably coupled to the rack and coupled in communication with the KVM switch system, the interactive display panel having a touch screen and keyboard viewable on a first side of the panel, the first side of the panel facing downward when in a retracted position, panel rotatable to expose the first side of the panel when extended from the rack.

17. The server system of claim 16, wherein the touch screen has a first zone for displaying video information and a second zone for operably displaying the keyboard.

18. The server system of claim 16, wherein the touch screen further comprises:
a third zone having a plurality of buttons displayed thereon and operable to generate a signal to the KVM switch system.
